(19) United States
(12) Patent Application Publication
(10) Pub. No.: US 2024/0291231 A1
(43) Pub. Date: Aug. 29, 2024

(54) LIGHT-EMITTING DEVICE AND METHOD OF MANUFACTURING COVER

(71) Applicant: NICHIA CORPORATION, Anan-shi (JP)

(72) Inventors: Tadayuki KITAJIMA, Tokushima (JP); Kazuma KOZURU, Anan-shi (JP)

(21) Appl. No.: 18/586,203

(22) Filed: Feb. 23, 2024

(30) Foreign Application Priority Data
Feb. 28, 2023 (JP) 2023-030076

(51) Int. Cl. H01S 5/0239; H01S 5/00

(52) U.S. Cl. CPC H01S 5/0239; H01S 5/0064; H01S 5/0087

(57) ABSTRACT

A light-emitting device includes a base member, a light-emitting element, and a cover. The cover has a lateral portion surrounding a periphery of the light-emitting element and an upper portion arranged above the light-emitting element. The cover includes a wavelength conversion member and a light-shielding member. The wavelength conversion member has an incident surface where the light emitted from the light-emitting element in the lateral direction is incident, at least a part of the wavelength conversion member constituting at least a part of the upper portion of the cover. A straight line, which passes through a light-emitting point of the light-emitting element and is parallel to an optical axis direction, passes through a part of the light-shielding member. At least the part of the light-shielding member is located, relative to the wavelength conversion member, on a side opposite from the light-emitting element in the optical axis direction.

### CROSS-REFERENCE TO RELATED APPLICATION

This application claims priority to Japanese Patent Application No. 2023-030076 filed on Feb. 28, 2023, the disclosure of which is hereby incorporated by reference in its entirety.

### BACKGROUND

The present disclosure relates to a light-emitting device and a method of manufacturing a cover.

JP 2016-167492 A discloses a light-emitting device that includes a laser diode, which is a light-emitting element, causes light emitted from the laser diode to enter a wavelength converter, converts the light enter the wavelength converter into light having a different wavelength, and outputs the light to the outside. In the light-emitting device disclosed in JP 2016-167492 A, a fitting portion having a recessed shape for fixing the wavelength converter is provided on the substrate, and the wavelength converter is fixed so as to be fitted into the fitting portion.

### SUMMARY

In the light-emitting device as described above, a traveling direction of the laser light emitted from the laser diode and a traveling direction of the light output from the light-emitting device are the same direction. In such a light-emitting device, when it is desired to increase the amount of the light converted by the wavelength converter, the wavelength converter is to be enlarged in the traveling direction of the laser light, which increases the size of the light-emitting device.

Alternatively, from another viewpoint, in the light-emitting device as described above, since a fitting portion for fitting the wavelength converter is used, the substrate has a complicated shape.

A light-emitting device according to one embodiment of the present disclosure includes a base member, a light-emitting element, and a cover. The light-emitting element is disposed on an upper surface of the base member and configured to emit light in a lateral direction. The cover is bonded to the base member and has a lateral portion surrounding a periphery of the light-emitting element and an upper portion arranged above the light-emitting element. The cover includes a wavelength conversion member and a light-shielding member. The wavelength conversion member has an incident surface where the light emitted from the light-emitting element in the lateral direction is incident, at least a part of the wavelength conversion member constituting at least a part of the upper portion of the cover. The light-shielding member is configured to shield light having a wavelength range identical to a wavelength range of the light emitted from the light-emitting element in the lateral direction. A straight line, which passes through a light-emitting point of the light-emitting element and is parallel to an optical axis direction, passes through a part of the light-shielding member, the optical axis direction being a direction in which the light emitted from the light-emitting element and passing along an optical axis travels. At least the part of the light-shielding member is located, relative to the wavelength conversion member, on a side opposite from the light-emitting element in the optical axis direction.

A method of manufacturing a cover according to one embodiment of the present disclosure includes: providing a wafer including a plurality of wavelength conversion members disposed two-dimensionally at a predetermined interval and one light-shielding member surrounding a lateral surface of each of the wavelength conversion members in a top view; forming a plurality of recesses opening on a lower surface of the wafer by removing a part of each of the wavelength conversion members and a part of the light-shielding member without penetrating through the wafer; and singulating the wafer into a plurality of pieces each constituting the cover by cutting the light-shielding member such that each of the pieces includes a corresponding one of the wavelength conversion members and a corresponding one of the recesses.

According to one embodiment of the present disclosure, a light-emitting device can be downsized in a direction of light emitted from the light-emitting element. In addition, a method of manufacturing a cover that allows downsizing of the light-emitting device can be provided.

Also, from another viewpoint, an easily manufacturable light-emitting device can be provided.

### BRIEF DESCRIPTION OF DRAWINGS

FIG. 1 is a schematic perspective view illustrating a light-emitting device according to a first embodiment.

FIG. 2 is a perspective view of the light-emitting device illustrated in FIG. 1, in a state in which a cover is removed.

FIG. 3 is a top view of the light-emitting device illustrated in FIG. 1, in a state in which the cover is removed.

FIG. 4 is a cross-sectional view of the light-emitting device taken along a cross-sectional line IV-IV in FIG. 1.

FIG. 5 is a top view illustrating the light-emitting device according to the first embodiment.

FIG. 6 is a bottom view illustrating the light-emitting device according to the first embodiment.

FIG. 7 is a perspective view illustrating a wavelength conversion member according to the first embodiment.

FIG. 8 is a top view illustrating a method of manufacturing the cover according to the first embodiment.

FIG. 9 is a cross-sectional view (No. 1) illustrating the method of manufacturing the cover according to the first embodiment.

FIG. 10 is a cross-sectional view (No. 2) illustrating the method of manufacturing the cover according to the first embodiment.

FIG. 11 is a cross-sectional view (No. 3) illustrating the method of manufacturing the cover according to the first embodiment.

FIG. 12 is a cross-sectional view (No. 4) illustrating the method of manufacturing the cover according to the first embodiment.

FIG. 13 is a cross-sectional view (No. 5) illustrating the method of manufacturing the cover according to the first embodiment.

FIG. 14 is an enlarged cross-sectional view of the light-emitting device illustrated in FIG. 4, in which a light-emitting element, the wavelength conversion member, and the vicinity thereof are illustrated in an enlarged manner.

### DETAILED DESCRIPTION

Hereinafter, certain embodiments of the invention will be described with reference to the drawings. Note that, in the following description, terms indicating a specific direction or position (e.g., “upper”, “lower”, and other terms including those terms) are used as necessary. The terms indicating directions and positions, such as “upper” and “lower”, used in the present description are used to clearly indicate relative directions and positional relationships of respective configurations and members, and need not coincide with, for example, the relationship at the time of use. The same reference numerals denote the same or similar portions or members appearing in multiple drawings.

In the present disclosure, a polygon, such as a triangle, rectangle, or the like, includes a polygonal shape with modified corners such as a rounded corner, a slanted corner, an inverted-round corner, or the like. The location of such modification is not limited to a corner (an end of a side). A shape with modification in the intermediate portion of a side will similarly be referred to as a polygon. That is, a polygon-based shape with partial modification should be understood to be included in the interpretation of a “polygon” described in the present disclosure.

This applies not only to polygons but also to words representing specific shapes such as trapezoids, circles, protrusions, and recesses. The same applies when dealing with a side forming that shape. That is, even when a corner or an intermediate portion of a certain side is modified, the interpretation of “side” includes the modified portion. When a “polygon” or a “side” without partial modification is to be distinguished from a processed shape, “strict” will be added to the description as in, for example, “strict quadrangle.”

The following embodiments exemplify light-emitting devices and the like for embodying the technical idea of the present invention, and the present invention is not limited to the description below. The dimensions, materials, shapes, relative arrangements, and the like of constituent elements described below are not intended to limit the scope of the present invention to those alone but are intended to provide an example, unless otherwise specified. The contents described in one embodiment can be applied to other embodiments and modification examples. The size, positional relationship, and the like of the members illustrated in the drawings can be exaggerated in order to clarify the explanation. Furthermore, in order to avoid excessive complication of the drawings, a schematic view in which some elements are not illustrated may be used, or an end view illustrating only a cutting surface may be used as a cross-sectional view.

### First Embodiment

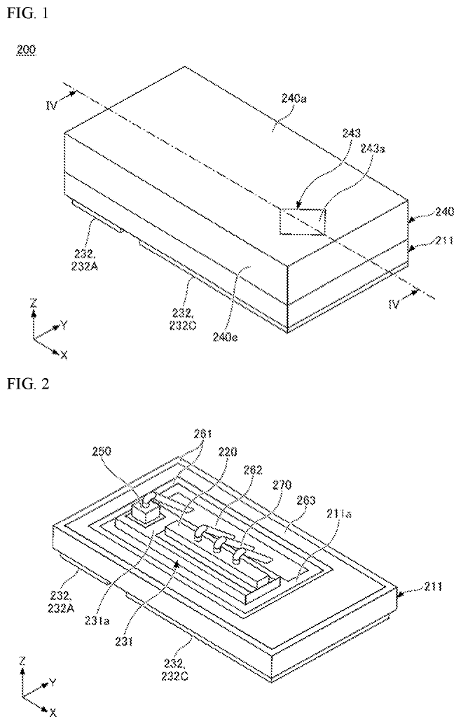

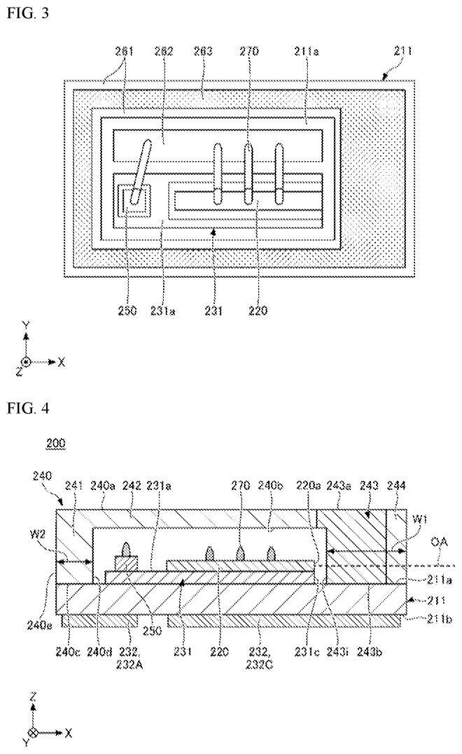

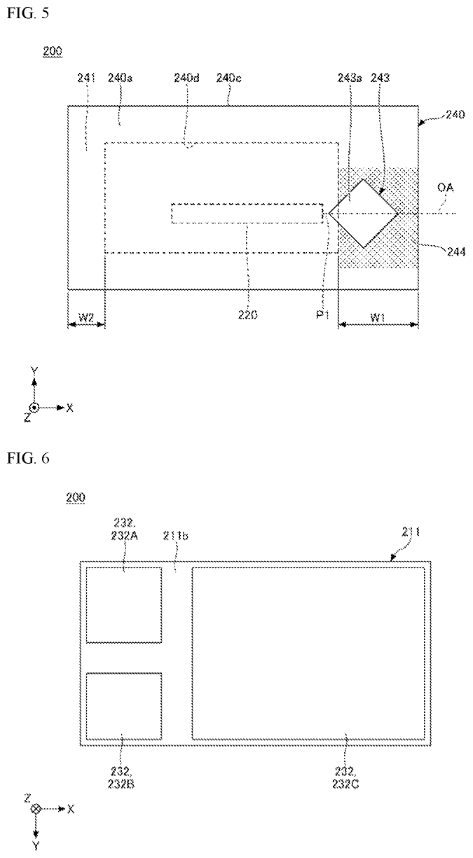

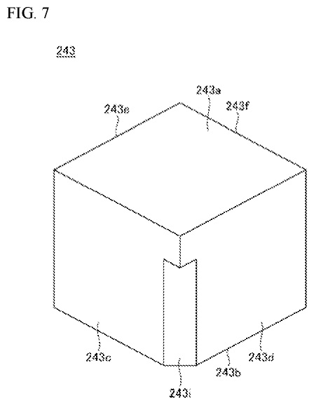

A light-emitting device 200 according to a first embodiment will be described with reference to FIGS. 1 to 7. FIG. 1 is a schematic perspective view illustrating a light-emitting device according to a first embodiment. FIG. 2 is a perspective view of the light-emitting device illustrated in FIG. 1, in a state in which a cover is removed. FIG. 3 is a top view of the light-emitting device illustrated in FIG. 1, in a state in which the cover is removed. FIG. 4 is a cross-sectional view of the light-emitting device taken along a cross-sectional line IV-IV in FIG. 1. FIG. 5 is a top view illustrating the light-emitting device according to the first embodiment. In FIG. 5, for convenience of explanation, the light-emitting element and an inner lateral surface of the cover are transparently illustrated by broken lines. FIG. 6 is a bottom view illustrating the light-emitting device according to the first embodiment. FIG. 7 is a perspective view illustrating a wavelength conversion member according to the first embodiment.

The light-emitting device 200 includes a base member 211, a light-emitting element 220, and a cover 240. In the example illustrated in the drawings, the light-emitting device 200 further includes an upper metal member 231, lower metal members 232, a protective element 250, and wiring members 270. The light-emitting device 200 need not include all of these components.

The components of the light-emitting device 200 will be described. Regarding the light-emitting device 200, the upper metal member 231 and the lower metal member 232 will be described together with the base member 211.

In FIGS. 1 to 6, an X-axis, a Y-axis, and a Z-axis that are mutually orthogonal are illustrated for reference. Directions parallel to the X-axis, the Y-axis, and the Z-axis are defined as a first direction X, a second direction Y, and a third direction Z, respectively. The first direction X and the second direction Y are parallel with the upper surface 211a of the base member 211, and the third direction Z is perpendicular to the upper surface 211a of the base member 211. In other drawings, the same or similar X-axis, Y-axis, and Z-axis are illustrated as necessary in some cases.

Base Member 211, Upper Metal Member 231, Lower Metal Member 232 The base member 211 has an upper surface 211a and a lower surface 211b. The upper surface 211a and the lower surface 211b may or may not be parallel to each other. The base member 211 includes one or more lateral surfaces that connect the upper surface 211a and the lower surface 211b. The one or more lateral surfaces connect an outer edge(s) of the upper surface 211a and an outer edge(s) of the lower surface 211b.

The base member 211 is, for example, a rectangular parallelepiped or a cube. In this case, both of the upper surface 211a and the lower surface 211b of the base member 211 have a rectangular shape, and the base member 211 includes four lateral surfaces each having a rectangular shape. A rectangular shape may include a square shape unless specifically described as excluding a square shape. The base member 211 need not be a rectangular parallelepiped or a cube. For example, the base member 211 may have a plate shape having any shape in a top view. The base member 211 is not limited to a plate shape and may have any shape, such as a circular shape, an elliptical shape, or a polygonal shape, in a top view.

The base member 211 contains, for example, a material having insulating properties. The base member 211 can be made of, for example, a ceramic as a main material. For example, aluminum nitride, silicon nitride, aluminum oxide, or silicon carbide can be used as the ceramic. The main material forming the base member 211 may be a conductive material. Examples include metal, such as aluminum, gold, silver, copper, tungsten, iron, nickel, cobalt, or an alloy thereof, diamond, or a composite material, such as copper diamond.

The upper metal member 231 is disposed on the upper surface 211a of the base member 211. The metal that forms the upper metal member 231 is, for example, copper. Examples of other materials that form the upper metal member 231 include copper-tungsten. A thickness of the upper metal member 231 is less than a thickness of the base member 211. The thickness of the upper metal member 231 is in a range of 30 μm to 120 μm, for example. With such a thickness, heat generated from the light-emitting element 220 can be sufficiently dissipated by the upper metal member 231.

The upper metal member 231 is provided at location closer to one of long sides that are opposite to each other in a short side direction of the upper surface 211a having a rectangular shape in a top view. To be more specific, the upper metal member 231 is provided at a location closer to a long side on the negative direction side of the second direction Y among the two long sides of the upper surface 211a. In the illustrated example, the upper metal member 231 has a rectangular shape in a top view. The upper metal member 231 need not be rectangular in a top view.

The one or more lower metal members 232 may be provided on the lower surface 211b of the base member 211. When the lower metal member 232 is provided on the lower surface 211b of the base member 211, a thickness of the lower metal member 232 is less than the thickness of the base member 211. The thickness of the lower metal member 232 is preferably in a range of 0.8 times to 1.2 times the thickness of the upper metal member 231. Accordingly, a bias of stresses on the upper surface 211a side and the lower surface 211b side of the base member 211 can be reduced, and an occurrence of warpage in the base member 211 can be suppressed. The thickness of the lower metal member 232 is, for example, in a range of 25 μm to 150 μm.

As illustrated in FIG. 6, in the light-emitting device 200, as an example, a plurality of the lower metal members 232 including a first lower metal member 232A, a second lower metal member 232B, and a third lower metal member 232C are provided on the lower surface 211b of the base member 211. In a bottom view, the first lower metal member 232A and the second lower metal member 232B are both disposed closer to one of two short sides of the lower surface 211b. In addition, the first lower metal member 232A and the second lower metal member 232B are disposed to face each other in the short side direction (the second direction Y).

In the illustrated example, the first lower metal member 232A is disposed at a location that is on the negative direction side of the first direction X and on the negative direction side of the second direction Y on the lower surface 211b. The second lower metal member 232B is disposed at a location on the negative direction side of the first direction X on the lower surface 211b, and on the positive direction side of the second direction Y relative to the first lower metal member 232A. In the illustrated example, the first lower metal member 232A and the second lower metal member 232B have the same size in the first direction X and the second direction Y. The first lower metal member 232A and the second lower metal member 232B may have sizes different from each other.

In a bottom view, the third lower metal member 232C is disposed to face the first lower metal member 232A and the second lower metal member 232B in the long side direction (the first direction X). To be more specific, the third lower metal member 232C is disposed on the positive direction side of the first direction X on the lower surface 211b, and faces the first lower metal member 232A and the second lower metal member 232B in the first direction X. In addition, in a bottom view, the third lower metal member 232C is spaced apart from the first lower metal member 232A and the second lower metal member 232B in the first direction X.

In both the long side direction (the first direction X) and the short side direction (the second direction Y) of the lower surface 211b, the third lower metal member 232C is longer than each of the first lower metal member 232A and the second lower metal member 232B. Also, in a bottom view, an area of the third lower metal member 232C is larger than the total of areas of the first lower metal member 232A and the second lower metal member 232B. In order to improve heat dissipation property, it is desirable that the area of the third lower metal member 232C be larger than ½ of an area of the lower surface 211b of the base member 211.

The first lower metal member 232A is electrically connected to the upper metal member 231 by, for example, a via wiring member penetrating through the base member 211. The second lower metal member 232B is electrically connected to a metal film 262 described below by, for example, the via wiring member penetrating through the base member 211. The first lower metal member 232A and the second lower metal member 232B can be used for electrical connection between the light-emitting element 220 and an external power supply, for example. The via wiring member need not be connected to the third lower metal member 232C. The third lower metal member 232C may be electrically floating.

A metal film 261 may be disposed on the upper surface 211a of the base member 211. As illustrated in FIG. 3, the metal film 261 is disposed to be spaced apart from the upper metal member 231 in a top view. A thickness of the metal film 261 in the third direction Z is preferably less than one third of the thickness of the upper metal member 231. In a top view, the metal film 261 is disposed to surround the periphery of the upper metal member 231, for example. The metal film 261 does not overlap with the upper metal member 231 in a top view. Examples of the metal film 261 include Ni/Au (metal film layered in the order of Ni and Au), Ti/Pt/Au (metal film layered in the order of Ti, Pt, and Au).

A metal film 262 may further be disposed on the upper surface 211a of the base member 211. As illustrated in FIG. 3, the metal film 262 is disposed to face the upper metal member 231. More specifically, the metal film 262 faces the upper metal member 231 in the second direction Y. The metal film 262 is located further in the positive direction of the second direction Y relative to the upper metal member 231. In a top view, the metal film 262 is rectangular and has a rectangular shape in which, for example, a length thereof in the first direction X is longer than a length thereof in the second direction Y. In a top view, the length of the metal film 262 in the first direction X is substantially the same as a length of the upper metal member 231 in the first direction X. In a top view, the length of the metal film 262 in the second direction Y is shorter than a length of the upper metal member 231 in the second direction Y. In a top view, the metal film 262 does not overlap with the upper metal member 231 or the metal film 261. In the illustrated example, the metal film 261 is provided to surround the periphery of the metal film 262.

As illustrated in FIG. 3, the upper surface of the metal film 261 may be provided with a metal adhesive 263 used for bonding to the cover 240 described below. In a top view, for example, the metal adhesive 263 is provided to surround the peripheries of the upper metal member 231 and the metal film 262. In the first direction X, a width of a portion of the metal adhesive 263 disposed on the positive direction side of the first direction X relative to the upper metal member 231 is greater than a width of a portion of the metal adhesive 263 disposed on the negative direction side of the first direction X. In addition, an area of the metal adhesive 263 is smaller than an area of the metal film 261 in a top view. As the metal adhesive 263, for example, AuSn can be used. In FIG. 3, for convenience, the metal adhesive 263 is illustrated in a dot pattern.

### Cover 240

The cover 240 includes an upper surface 240a, a back surface 240b, a lower surface 240c, one or more inner lateral surfaces 240d, and one or more outer lateral surfaces 240e. In the third direction Z, the back surface 240b is located further in the negative direction relative to the upper surface 240a, and the lower surface 240c is located still further in the negative direction relative to the back surface 240b. The upper surface 240a, the back surface 240b, and the lower surface 240c may be parallel to each other or need not be parallel to each other. The one or more inner lateral surfaces 240d meet the back surface 240b and the lower surface 240c. The one or more outer lateral surfaces 240e meet the upper surface 240a and the lower surface 240c.

In the description below, to describe the configuration of the cover 240, a lateral portion 241 and an upper portion 242 will be described separately. In the present description the “lateral portion 241” refers to a portion of the cover 240 that is located on the lower surface 240c side relative to a plane that overlaps with the back surface 240b and is parallel to the back surface 240b. The “upper portion 242” refers to a portion of the cover 240 that is located on the upper surface 240a side relative to the plane that overlaps with the back surface 240b and is parallel to the back surface 240b. In the illustrated example, a portion located further in the negative direction of the third direction Z relative to the back surface 240b is referred to as the “lateral portion 241”. A portion located further in the positive direction of the third direction Z relative to the back surface 240b is referred to as the “upper portion 242”.

The lateral portion 241 has a rectangular frame-like shape in a top view, for example. The upper portion 242 has a plate-like shape, for example. An upper end side of the lateral portion 241 is closed by the upper portion 242, and a lower end side of the lateral portion 241 is open. That is, the cover 240 has a recessed shape opening on a side opposite to the upper portion 242. In a top view, an outer shape of the cover 240 is rectangular, for example. The outer shape of the cover 240 in a top view need not be rectangular, and may be, for example, polygonal other than rectangular, circular, or the like.

The cover 240 includes a wavelength conversion member 243. At least a part of the wavelength conversion member 243 is included in the lateral portion 241. Furthermore, at least a part of the wavelength conversion member 243 is included in the upper portion 242. The wavelength conversion member 243 includes an upper surface 243a, a lower surface 243b that is a surface opposite to the upper surface 243a, and a plurality of lateral surfaces. In a top plan view, the shape of the lower surface 243b and the shape of the upper surface 243a are different.

In the example in FIG. 7, the wavelength conversion member 243 includes an incident lateral surface 243i, a first lateral surface 243c, a second lateral surface 243d, a third lateral surface 243e, and a fourth lateral surface 243f as the plurality of lateral surfaces. In the wavelength conversion member 243, the incident lateral surface 243i can be a light incident surface. The upper surface 243a can be an emission surface through which light incident on the incident lateral surface 243i and wavelength-converted by the wavelength conversion member 243 exits upward.

The first lateral surface 243c, the second lateral surface 243d, the third lateral surface 243e, and the fourth lateral surface 243f are connected with outer edges of the upper surface 243a and outer edges of the lower surface 243b. The third lateral surface 243e is connected with each of the first lateral surface 243c and the fourth lateral surface 243f. The fourth lateral surface 243f is connected with each of the second lateral surface 243d and the third lateral surface 243e. The first lateral surface 243c and the fourth lateral surface 243f are not connected with each other. The second lateral surface 243d and the third lateral surface 243e are not connected with each other.

The first lateral surface 243c and the second lateral surface 243d are connected with each other on an upper side and are each connected with the incident lateral surface 243i on a lower side. The first lateral surface 243c and the second lateral surface 243d are connected with each other on an upper side relative to an intermediate point between the upper surface 243a and the lower surface 243b in a direction perpendicular to the upper surface 243a. Furthermore, they are each connected with the incident lateral surface 243i on a lower side relative to the intermediate point. For example, this intermediate point is the uppermost point of the incident lateral surface 243i. At a lower side of the incident lateral surface 243i, the incident lateral surface 243i is connected with the outer edge of the lower surface 243b.

The incident lateral surface 243i is located on an inner side relative to a side where the first lateral surface 243c and the second lateral surface 243d are connected with each other. In other words, the incident lateral surface 243i is located closer to a side at which the third lateral surface 243e and the fourth lateral surface 243f are connected together than the side at which the first lateral surface 243c and the second lateral surface 243d are connected together is to the side at which the third lateral surface 243e and the fourth lateral surface 243f are connected together. That is, the wavelength conversion member 243 has a shape recessed inward relative to the side where the first lateral surface 243c and the second lateral surface 243d are connected with each other on the incident lateral surface 243i.

In the illustrated example, the wavelength conversion member 243 has a lower surface connected with the incident lateral surface 243i, the first lateral surface 243c, and the second lateral surface 243d. This lower surface is located between the upper surface 243a and the lower surface 243b in a direction perpendicular to the upper surface 243a. For example, this lower surface can be flat and parallel to the upper surface 243a and the lower surface 243b. The wavelength conversion member 243 need not have this lower surface. For example, the wavelength conversion member 243 may alternatively include, on an upper side of the incident lateral surface 243i, an inclined surface that is inclined toward the side where the first lateral surface 243c and the second lateral surface 243d are connected with each other. Also, this inclined surface need not be flat and may have a curved surface shape. For example, on a distance from the side at which the first lateral surface 243c and the second lateral surface 243d are connected with each other may be gradually reduced from the lower side of the incident lateral surface 243i toward the upper side of the incident lateral surface 243i.

In a top view, the first lateral surface 243c and the fourth lateral surface 243f may be parallel to each other. In a top view, the second lateral surface 243d and the third lateral surface 243e may be parallel to each other. In a top view, the first lateral surface 243c and the second lateral surface 243d may be perpendicular to each other, the first lateral surface 243c and the third lateral surface 243e may be perpendicular to each other, the third lateral surface 243e and the fourth lateral surface 243f may be perpendicular to each other, and the fourth lateral surface 243f and the second lateral surface 243d may be perpendicular to each other.

The cover 240 includes a light-shielding member 244. The light-shielding member 244 preferably covers large portions of the respective lateral surfaces except the incident lateral surface 243i of the wavelength conversion member 243. Here, “large portions” mean that the light-shielding member 244 covers 80% or more of areas of the respective lateral surfaces except the incident lateral surface 243i. The light-shielding member 244 can shield light in the same wavelength range as the light incident on the incident lateral surface 243i of the wavelength conversion member 243. Preferably, the light-shielding member 244 does not transmit 90% or more, more preferably does not transmit 95% or more, and even more preferably does not transmit 99% or more of light in the same wavelength range as the light incident on the incident lateral surface 243i. In the example herein, the light-shielding member 244 may have reflectivity. The phrase “having reflectivity” used herein means, for example, having a reflectance of 80% or more for light having a specific wavelength.

In the lateral portion 241 and the upper portion 242 of the cover 240, the entire portion except the wavelength conversion member 243 may be the light-shielding member 244. For example, the first lateral surface 243c and the second lateral surface 243d of the wavelength conversion member 243 are covered by the light-shielding member 244 and are not exposed. Similarly, for example, the third lateral surface 243e and the fourth lateral surface 243f of the wavelength conversion member 243 are covered by the light-shielding member 244 and are not exposed. In addition, for example, the upper surface 243a is not covered by the light-shielding member 244 and is exposed. Similarly, for example, the incident lateral surface 243i is not covered by the light-shielding member 244 and is exposed. In the illustrated example, the lower surface 243b is also not covered by the light-shielding member 244 and is exposed.

At least a part of the upper surface 240a of the cover 240 includes the upper surface 243a of the wavelength conversion member 243. The upper surface 240a of the cover 240 including the upper surface 243a may constitute one plane. At least a part of the lower surface 240c of the cover 240 includes the lower surface 243b. The lower surface 240c of the cover 240 including the lower surface 243b may constitute one plane. At least a part of an inner lateral surface 240d of the cover 240 includes the incident lateral surface 243i. The above-described lower surface connected with the incident lateral surface 243i, the first lateral surface 243c, and the second lateral surface 243d may be included in at least a part of the back surface 240b of the cover 240. When this lower surface is an inclined surface, the inclined surface is included at least partially in both or one of the back surface 240b and an inner lateral surface 240d of the cover 240. Furthermore, the outer lateral surfaces 240e of the cover 240 may be entirely made of outer lateral surfaces of the light-shielding member 244. That is, the outer lateral surfaces 240e of the cover 240 can be configured not to have a region in which the wavelength conversion member 243 is exposed.

The wavelength conversion member 243 is to be irradiated with light. Accordingly, an inorganic material that is not easily decomposed by irradiation of the light is preferably used as a main material of a base material of the wavelength conversion member 243. The main material is, for example, a ceramic. In a case in which the main material of the wavelength conversion member 243 is a ceramic, examples of the ceramic include aluminum oxide, aluminum nitride, silicon oxide, yttrium oxide, zirconium oxide, or magnesium oxide. As the main material of the ceramic, it is preferable to select a material having a melting point in a range of 1300° C. to 2500° C. such that deterioration, such as deformation or discoloration due to heat, does not occur in the wavelength conversion member 243. As used herein, the term “main material” of a specific member refers to a material that occupies the largest ratio of the components in terms of a weight ratio or a volume ratio. The term “main material” may also include a case in which no other materials are included, that is, only the main material is used to form the component. Note that the wavelength conversion member 243 may be made of a material other than the ceramic as the main material.

The wavelength conversion member 243 includes a phosphor. The wavelength conversion member 243 can be made by sintering, for example, a phosphor and aluminum oxide and the like. The content of the phosphor can be in a range of 0.05 vol % to 50 vol % relative to the total volume of the ceramic. For example, a ceramic substantially including only a phosphor, which is obtained by sintering the powder of the phosphor, may be used. Furthermore, the wavelength conversion member 243 may be made of a single crystal of the phosphor.

Examples of the phosphor include cerium-activated yttrium aluminum garnet (YAG), cerium-activated lutetium aluminum garnet (LAG), europium-activated silicate ((Sr, Ba)₂SiO₄), α-SiAlON phosphor, and β-SiAlON phosphor. Among them, the YAG phosphor has good heat resistance.

The light-shielding member 244 is, for example, a sintered compact formed using a ceramic as the main material. The ceramic used for the main material includes, for example, aluminum oxide, aluminum nitride, silicon oxide, yttrium oxide, zirconium oxide, and magnesium oxide. The main material of the light-shielding member 244 may be a material other than a ceramic, and may be made using, for example, a metal, a composite of a ceramic and a metal, or a resin.

In the cover 240, the wavelength conversion member 243 and the light-shielding member 244 can be integrally formed. That is, in the cover 240, the lateral portion 241 and the upper portion 242 can be integrally formed. The cover 240 may be made by separately forming the wavelength conversion member 243 and the light-shielding member 244 and bonding them together. The wavelength conversion member 243 and the light-shielding member 244 are, for example, an integrated sintered compact.

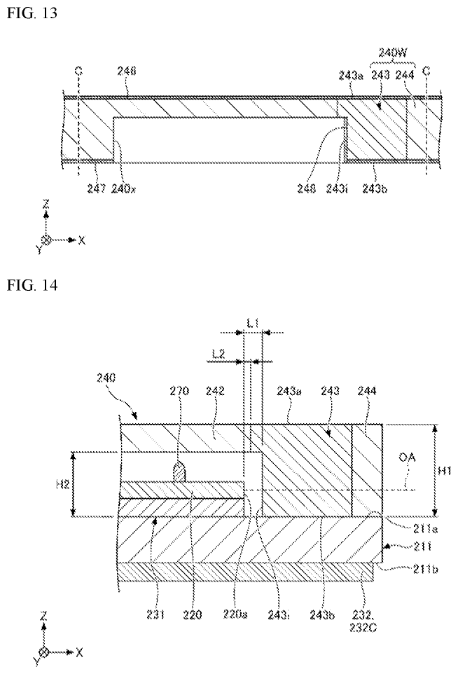

The cover 240 may include an anti-reflective film on the upper surface 240a (e.g., the anti-reflective film 246 shown in FIGS. 12 and 13). The cover 240 may include a metal film on the lower surface 240c (e.g., the metal film 247 shown in FIGS. 12 and 13). The wavelength conversion member 243 may include a reflective film on the incident lateral surface 243i (e.g., the reflective film 248 shown in FIG. 13).

### Light-Emitting Element 220

The light-emitting element 220 is, for example, a semiconductor laser element. The light-emitting element 220 is not limited to a semiconductor laser element and may be, for example, a light-emitting diode (LED) or an organic light-emitting diode (OLED). In the light-emitting device 200 illustrated in the drawings, a semiconductor laser element is used as the light-emitting element 220.

The light-emitting element 220 has, for example, a rectangular outer shape in the top view. A lateral surface meeting one of two short sides of the rectangle is an emitting end surface 220a for light emitted from the light-emitting element 220. An upper surface and a lower surface of the light-emitting element 220 each have an area larger than the emitting end surface 220a. A metal film may be provided on the upper surface of the light-emitting element 220. This metal film is provided with, for example, wiring members for conduction with other members. The upper surface of the light-emitting element 220 need not be provided with a metal film.

Here, a case in which the light-emitting element 220 is a semiconductor laser element will be described. The light (laser light) emitted from the light-emitting element 220 diverges and forms an elliptical far field pattern (hereinafter referred to as “FFP”) on a plane parallel to the emitting end surface. Here, the FFP indicates a shape and a light intensity distribution of the emitted light at a position away from the emitting end surface.

Based on the light having elliptical shape emitted from the light-emitting element 220, a direction along the major axis of the elliptical shape is referred to as a fast axis direction of the FFP, and a direction along the minor axis of the elliptical shape is referred to as a slow axis direction of the FFP. The fast axis direction of the FFP in the light-emitting element 220 can coincide with a layering direction in which a plurality of semiconductor layers including an active layer of the light-emitting element 220 are layered.

Based on the light intensity distribution of the FFP of the light-emitting element 220, light having an intensity of 1/e² times or greater of a peak intensity value is referred to as a main part of light. In this light intensity distribution, an angle corresponding to the intensity of 1/e² is referred to as a divergence angle. The divergence angle of the FFP in the fast axis direction is greater than the divergence angle of the FFP in the slow axis direction.

Furthermore, light at the center of the elliptical shape of the FFP, in other words, light having a peak intensity in the light intensity distribution of the FFP, is referred to as light traveling along an optical axis or light passing along an optical axis. Furthermore, an optical path of the light traveling along the center of the elliptical shape of the FFP is referred to as the optical axis of the light.

A light-emitting element configured to emit visible light can be used as the light-emitting element 220. Examples of the light-emitting element that configured to emit visible light include light-emitting elements configured to emit blue light, green light, and red light. As used herein, “light-emitting elements configured to emit blue light, green light, and red light” refer to light-emitting elements having emission peak wavelengths in a range of 405 nm to 494 nm, in a range of 495 nm to 570 nm, and in a range of 605 nm to 750 nm, respectively. Examples of the light-emitting element 220 configured to emit blue light or green light include a semiconductor laser element including a nitride semiconductor. As the nitride semiconductor, for example, GaN, InGaN, or AlGaN can be used. Examples of the light-emitting element 220 configured to emit red light include a semiconductor laser element including an InAlGaP-based, GaInP-based, GaAs-based, or AlGaAs-based semiconductor.

The emission peak of the light emitted from the light-emitting element 220 is not limited to those described above. For example, the light emitted from the light-emitting element 220 may be visible light of a color other than the colors described above, and a light-emitting element that emits ultraviolet light, infrared light, or the like in addition to visible light may also be used.

### Protective Element 250

The protective element 250 is a component for protecting specific elements such as semiconductor laser elements. The protective element 250 is a component for preventing specific elements such as semiconductor laser elements from being broken by an excessive current flowing therethrough, for example. For example, a Zener diode made of Si can be used as the protective element 250. In addition to the protective element 250, a temperature measuring element, such as a thermistor, may be provided. When the temperature measuring element is provided, the temperature measuring element is preferably disposed near the emitting end surface of the light-emitting element 220.

### Wiring Member 270

The wiring member 270 is made from a conductor having a linear shape with bonding portions at both ends. In other words, the wiring member 270 includes the bonding portions that are to be bonded to other components, at both ends of the linear portion. The wiring member 270 is used for electrical connection between two components. For example, a metal wire can be used as the wiring member 270. Examples of the metal include gold, aluminum, silver, copper, and tungsten.

### Method of Manufacturing Cover 240

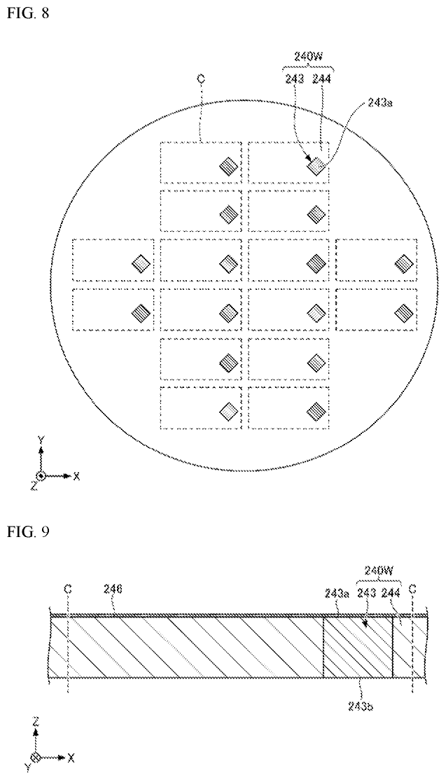

FIGS. 8 to 13 are diagrams illustrating a method of manufacturing the covers according to the present embodiment. In the description below, as an example, a case in which the entire portion of the cover 240 except the wavelength conversion member 243 is the light-shielding member 244 will be described.

As illustrated in FIG. 8, for example, a wafer 240W including a plurality of the wavelength conversion members 243 disposed two-dimensionally at a predetermined interval and one light-shielding member 244 surrounding the lateral surfaces of the respective wavelength conversion members 243, in a top view, is provided (first step). The plurality of wavelength conversion members 243 are disposed in a matrix pattern. In the wafer 240W, the upper surface 243a and the lower surface of each of the wavelength conversion members 243 are exposed from the light-shielding member 244. The upper surface 243a of each of the wavelength conversion members 243 and the upper surface of the light-shielding member 244 may form one continuous flat plane. Furthermore, the lower surface of each of the wavelength conversion members 243 and the lower surface of the light-shielding member 244 may form one continuous flat plane. In FIG. 8, for convenience, regions to be cut into the covers 240 are indicated by broken lines C.

Specifically, the plurality of wavelength conversion members 243 are provided, and the respective wavelength conversion members 243 are temporarily fixed on a support at a predetermined interval. The respective wavelength conversion members 243 are ceramic containing a phosphor, for example. Subsequently, a molded body is formed on the support so as to surround the upper surfaces 243a and the lateral surfaces of the respective wavelength conversion members 243. The molded body includes, for example, a light reflecting powder made of a ceramic as a main material. The molded body can be molded using a slip casting method, a doctor blade method (sheet forming method), a dry molding method, or the like. Subsequently, the wavelength conversion members 243 and the molded body are removed from the support and then calcined at a predetermined temperature. At this time, the sintering conditions of the molded body can be adjusted such that the molded body includes more voids than the wavelength conversion members 243. After calcination, the molded body covering the upper surfaces 243a of the wavelength conversion members 243 is removed by polishing or the like, and the upper surfaces 243a of the wavelength conversion members 243 are exposed. Furthermore, as necessary, the lower surfaces of the wavelength conversion members 243 and the molded body are flattened by polishing or the like. Accordingly, the wafer 240W including the plurality of wavelength conversion members 243 and one light-shielding member 244 surrounding the lateral surfaces of each of the wavelength conversion members 243 is obtained. The following description will be made with reference to a vertical cross-sectional view of one region surrounded by the broken lines C in FIG. 8 and the vicinity thereof.

Subsequently, as illustrated in FIG. 9, as necessary, an anti-reflective film 246 may be formed on the entire upper surface of the wafer 240W (second step). The anti-reflective film 246 can be formed, for example, by layering one or more dielectric multilayer films of, for example, Nb₂O₅/SiO₂, Ta₂O₅/SiO₂, Al₂O₃/SiO₂, ZrO₂/SiO₂, or ZrO₂/Al₂O₃. The anti-reflective film 246 can be formed by, for example, sputtering. With the anti-reflective film 246, light that is to exit through the upper surface 243a of the wavelength conversion member 243 to the outside can be hindered from being internally reflected at the upper surface 243a of the wavelength conversion member 243, and thus, it is possible to increase exit efficiency of the light exiting from the upper surface 243a of the wavelength conversion member 243 to the outside.

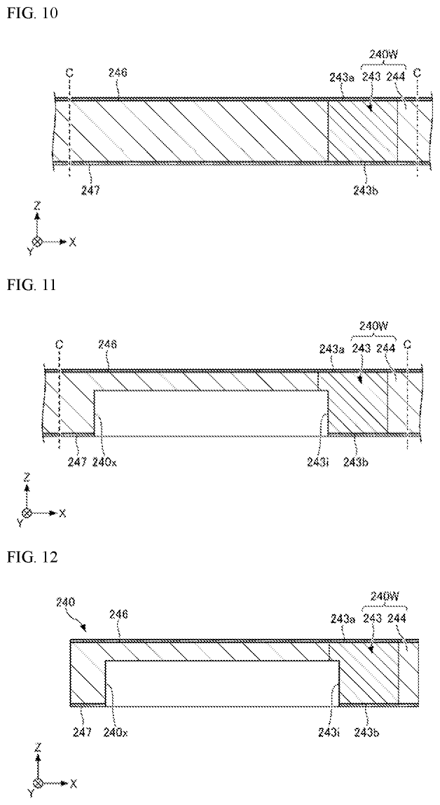

Subsequently, as illustrated in FIG. 10, as necessary, a metal film 247 may be formed on the entire lower surface of the wafer 240W (third step). As the metal film 247, Ti/Ag/Ti/Pt/Au (metal film layered in the order of Ti, Ag, Ti, Pt, and Au) or Ti/Al/Ti/Pt/Au (metal film layered in the order of Ti, Al, Ti, Pt, and Au) can be used, for example. The metal film 247 can be formed by, for example, sputtering. The metal film 247 can be used when the cover 240 is bonded to another member. Furthermore, the metal film 247 provided on the lower surface of the cover 240 can serve as a light reflective film that upwardly reflects the light that has reached the lower surface 243b of the wavelength conversion member 243. Among the metals constituting the metal film 247, Ag and Al are metals having relatively high reflectivity, making it possible to upwardly reflect the light that has reached the lower surface 243b of the wavelength conversion member 243 and thus increase the exit efficiency of light exiting from the upper surface 243a of the wavelength conversion member 243 to the outside. A light reflective film formed using a material other than metal may be employed instead of the metal film 247. For example, the light reflective film can be formed by, for example, layering one or more dielectric multilayer films of, for example, Nb₂O₅/SiO₂, TiO₂/SiO₂, or Ta₂O₅/SiO₂.

Subsequently, as illustrated in FIG. 11, a part of each of the wavelength conversion members 243 and parts of the light-shielding member 244 are removed without penetrating through from the lower surface to the upper surface of the wafer 240W, and a plurality of recesses 240x opening on the lower surface of the wafer 240W is formed (fourth step). For example, parts of the metal film 247, the wavelength conversion members 243, and the light-shielding member 244 are removed by blasting from the lower surface side of the wafer 240W to a predetermined height, and the recesses 240x opening on the lower surface of the wafer 240W are formed. Accordingly, a part of a lateral surface of the wavelength conversion member 243 is exposed in the recess 240x and the incident lateral surface 243i is formed.

Subsequently, as illustrated in FIG. 12, the light-shielding member 244 is cut into pieces such that a piece of the pieces includes one wavelength conversion member 243 and one recess 240x, thereby singulating the wafer 240W (fifth step). Specifically, the light-shielding member 244 is cut in vertical directions at the positions of the broken lines C illustrated in FIG. 8 and the like to be singulated into a plurality of the covers 240. In a top view, the light-shielding member 244 is cut such that the light-shielding member 244 remains in the periphery of the recess 240x formed by the fourth step. In addition, the light-shielding member 244 is cut such that the light-shielding member 244 surrounds the lateral surfaces of the wavelength conversion member 243 excluding the incident lateral surface 243i. A blade or a laser, for example, can be used for cutting.

After the step illustrated in FIG. 11, as illustrated in FIG. 13, a step of forming a reflective film 248 on the incident lateral surface 243i of the wavelength conversion member 243 exposed in the recess 240x may be performed. The reflective film 248 may extend from an upper end of the incident lateral surface 243i of the wavelength conversion member 243 to the light-shielding member 244 side in the recess 240x. The reflective film 248 is an optical film that reflects light at a particular wavelength and transmits light at other wavelengths. A DBR film is used as the reflective film 248, for example. In a DBR film, for example, films having different refractive indices with a thickness of ¼ wavelength are alternately layered, which allows for reflecting a predetermined wavelength at high efficiency. The DBR film can contain at least one type of oxide or nitride of a material selected from the group consisting of, for example, Si, Ti, Zr, Nb, Ta, and Al. With the reflective film 248, the light incident on the incident lateral surface 243i from the outside can be transmitted to the wavelength conversion member 243, and 90% or more of the light that is wavelength-converted by the wavelength conversion member 243 can be reflected.

Thus, it is possible to achieve a method of manufacturing the covers 240 that enables downsizing of the light-emitting device 200. That is, in the cover 240, the wavelength conversion member 243 that wavelength-converts the wavelength of the light from the light-emitting element 220 and outputs the light to the outside constitutes a part of the cover 240. Accordingly, when the light-emitting device 200 is constituted using the cover 240, it is not necessary to additionally provide a member for covering the wavelength conversion member 243 or the light-emitting element 220 separately from the cover 240. Thus, the light-emitting device 200 can be downsized. Moreover, using the cover 240 including the wavelength conversion member 243 allows for reducing the number of components of the light-emitting device 200, which allows for realizing the light-emitting device 200 that can be easily manufactured.

### Light-Emitting Device 200

The light-emitting device 200 will be described.

The light-emitting element 220 is disposed on the upper surface 211a of the base member 211. More specifically, the light-emitting element 220 is disposed on the upper surface 211a of the base member 211 via the upper metal member 231. The light-emitting element 220 is bonded to an upper surface 231a of the upper metal member 231. For example, a length from the upper surface 211a of the base member 211 to the lower surface of the light-emitting element 220 can be 100 μm or less. In addition, for example, the light-emitting element 220 includes a metal film on the lower surface thereof, and this metal film is bonded to the metal film provided on the upper surface 231a of the upper metal member 231 via, for example, a metal adhesive. Examples of the metal adhesive used for this bonding include AuSn. Thicknesses of the metal film provided on the lower surface of the light-emitting element 220 and the metal film provided on the upper surface 231a of the upper metal member 231 can be about the same as the thickness of the metal film 261.

In a top view as seen along a direction perpendicular to the upper surface 211a of the base member 211, the light-emitting element 220 is laterally surrounded by the lateral portion 241. Hereinafter, in the description of the light-emitting device, a “top view” refers to a “top view” in a direction perpendicular to the upper surface 211a of the base member 211 unless otherwise specified. The light-emitting element 220 emits light laterally from the emitting end surface 220a. In the illustrated example, the direction of an optical axis OA, which is the direction of the light emitted from the emitting end surface 220a of the light-emitting element 220, is parallel to the first direction X. The light emitted from the light-emitting element 220 is, for example, blue light. The light emitted from the light-emitting element 220 is not limited to the blue light. In the example illustrated in the drawings, the light-emitting element 220 is a semiconductor laser element.

The light-emitting element 220 is disposed such that the emitting end surface 220a is oriented in the same direction as that in which one of lateral surfaces 231c of the upper metal member 231 is oriented. That is, the upper metal member 231 has the lateral surface 231c oriented in the same direction as the emitting end surface 220a. The emitting end surface 220a of the light-emitting element 220 is perpendicular to the first direction X. The emitting end surface 220a of the light-emitting element 220 can be, for example, parallel or perpendicular to one inner lateral surface 240d or one outer lateral surface 240e of the cover 240. The entire light-emitting element 220 is preferably located on the upper surface 231a of the upper metal member 231. Thus, the heat dissipation property of the light-emitting element 220 can be improved.

The protective element 250 is disposed on the upper surface 231a of the upper metal member 231 on which the light-emitting element 220 is disposed. Thus, a function to protect the light-emitting element 220 can be improved. In the illustrated example, the protective element 250 is disposed further in the negative direction of the first direction X and at substantially the same position in the second direction Y relative to the light-emitting element 220.

One or more wiring members 270 that is electrically connected to the light-emitting element 220 are bonded to the upper surface of the metal film 262. A wiring member 270 that is electrically connected to the protective element 250 is bonded to the upper surface of the metal film 262. That is, in the light-emitting device 200, the light-emitting element 220 and the protective element 250 are each electrically connected to the metal film 262 of the base member 211 by the plurality of wiring members 270.

In the second direction Y, the light-emitting element 220 and the protective element 250 are offset to the negative direction side in the second direction Y relative to the center in the short direction of the upper surface 211a of the base member 211. The light-emitting element 220 is disposed at the center of the upper surface 211a of the base member 211 and the vicinity thereof in the first X direction.

The lower surface 240c of the cover 240 is bonded to an outer edge of the upper surface 211a of the base member 211. For example, the metal film provided on the lower surface 240c of the cover 240 and the metal film 261 provided on the upper surface 211a of the base member 211 are bonded and fixed together via the metal adhesive 263. Accordingly, the lower surface 240c of the cover 240 is bonded to the upper surface 211a having a planar shape. With this configuration, it is not necessary to provide, on the upper surface 211a of the base member, a complicated fitting portion, such as a step or a recessed portion, for fitting the cover 240 thereto. The metal film 261 may be provided, on the upper surface 211a of the base member 211, at a position to which the lower surface 243b of the wavelength conversion member 243 is bonded. Accordingly, heat dissipation property for the heat generated by the wavelength conversion member 243 of the light-emitting device 200 can be improved.

The cover 240 is bonded to the upper surface 211a of the base member 211 such that the lateral portion 241 surrounds the periphery of the light-emitting element 220 and the upper portion 242 covers the light-emitting element 220 from above. Accordingly, a closed space surrounded by the lateral portion 241 and the upper portion 242 of the cover 240 and the base member 211 is formed. This closed space may be formed, for example, in a sealed state. With this closed space being in the sealed state, attraction of dust, such as organic substances, on the emitting end surface 220a of the light-emitting element 220 can be reduced.

As illustrated in FIGS. 4 and 5, the wavelength conversion member 243 is disposed laterally to the light-emitting element 220. More specifically, the wavelength conversion member 243 is disposed at a position on which light that is emitted from the light-emitting element 220 and travels laterally is incident. In the illustrated example, the wavelength conversion member 243 is located further in the positive direction of the first direction X relative to the light-emitting element 220. Furthermore, the wavelength conversion member 243 is located on the optical axis OA of the light emitted laterally from the light-emitting element 220. The incident lateral surface 243i of the wavelength conversion member 243 is disposed to face the emitting end surface 220a of the light-emitting element 220. In other words, the incident lateral surface 243i faces the emitting end surface 220a in the first direction X.

In a bottom view, an extension line of a side at which the first lateral surface 243c and the lower surface 243b of the wavelength conversion member 243 meet and an extension line of a side at which the second lateral surface 243d and the lower surface 243b of the wavelength conversion member 243 meet intersect with each other at a location further in the negative direction of the first direction X relative to the incident lateral surface 243i. In other words, the two extension lines intersect with each other at a location closer to the light-emitting element 220 side relative to the incident lateral surface 243i. Also, in a bottom view, the third lateral surface 243e and the fourth lateral surface 243f of the wavelength conversion member 243 intersect with each other at a location further in the positive direction of the first direction X, which is a side opposite to the light-emitting element 220, relative to the incident lateral surface 243i.

The light emitted from the emitting end surface 220a of the light-emitting element 220 and traveling laterally is incident on the incident lateral surface 243i of the wavelength conversion member 243 and is wavelength-converted by the wavelength conversion member 243. Furthermore, the wavelength-converted light exits upward from the upper surface 243a. Thus, in the illustrated example, the upper surface 243a is the emission surface of the wavelength conversion member 243. In the wavelength conversion member 243 of the present embodiment, an extended plane of the incident lateral surface 243i and an extended plane of the upper surface 243a, which is the emission surface, intersect with each other. In the illustrated example, the extended plane of the incident lateral surface 243i and the extended plane of the upper surface 243a perpendicularly intersect with each other. Thus, the traveling direction of the light incident on the incident lateral surface 243i can be different from the traveling direction of the light exiting from the upper surface 243a. Even when the amount of light that is wavelength-converted by the wavelength conversion member 243 is increased, it is possible to suppress an increase in the size of the wavelength conversion member 243 in the first direction X, which is the traveling direction of the light emitted from the emitting end surface 220a. At least a part of the incident lateral surface 243i is located below the optical axis OA. Accordingly, among the light emitted from the light-emitting element 220, light that travels below the optical axis OA is allowed to efficiently enter the wavelength conversion member 243 through the incident lateral surface 243i.

As illustrated in FIG. 5, a straight line, which passes through a light-emitting point P1 of the light-emitting element 220 and is parallel to an optical axis direction, passes through the light-shielding member 244. The optical axis direction is a direction in which light emitted from the light-emitting element 220 and passing along the optical axis OA travels. At least a part of the light-shielding member 244 is located at a position away from the wavelength conversion member 243 in the optical axis OA direction. In other words, at least a part of the light-shielding member 244 is located, relative to the wavelength conversion member 243, further toward a side opposite to the light-emitting element 220 on the optical axis OA.

The light-shielding member 244 will be further described with reference to FIGS. 5 and 7. In the wavelength conversion member 243, the lateral surfaces of the wavelength conversion member 243 except the incident lateral surface 243i are covered by the light-shielding member 244. Accordingly, when the light entered the wavelength conversion member 243 from the light-emitting element 220 reaches interfaces between the other lateral surfaces of the wavelength conversion member 243 and the light-shielding member 244, the light is shielded by the light-shielding member 244. Therefore, it is possible to reduce the possibility that the light entered the wavelength conversion member 243 from the light-emitting element 220 exits to the outside from the outer lateral surface 240e of the cover 240. When the light-shielding member 244 has reflectivity, the light entered the wavelength conversion member 243 from the light-emitting element 220 is reflected at the interface with the light-shielding member 244. Accordingly, the exit efficiency of the light exiting to the outside from the upper surface 243a of the wavelength conversion member 243 can be increased.

As exemplified in the portion illustrated in a dot pattern in FIG. 5, the light-shielding member 244 is provided at least in a portion that covers the lateral surfaces of the wavelength conversion member 243. More specifically, the light-shielding member 244 is provided across the lateral portion 241 and the upper portion 242 of the cover 240. For example, the cover 240 may have a different configuration in addition to the wavelength conversion member 243 and the light-shielding member 244.

In the illustrated example, the light-shielding member 244 covers the light-emitting element 220 in a top view. In a top view, the light-shielding member 244 preferably covers 80% or more of the upper surface of the light-emitting element 220. Accordingly, it is possible to reduce the possibility that, among the light emitted from the light-emitting element 220, light that does not enter the wavelength conversion member 243 exits to the outside. Furthermore, the lateral portion 241 located on the side opposite to the wavelength conversion member 243 in the optical axis OA direction is the light-shielding member 244. In this case, a lateral surface of the light-emitting element 220 located on the side opposite to the emitting end surface 220a of the light-emitting element 220 faces the light-shielding member 244. In the cover 240, the lateral portion 241 and the upper portion 242 excluding the wavelength conversion member 243 may entirely be the light-shielding member 244.

In the example of FIGS. 4 and 5, the direction of the optical axis OA of the emitted light does not change while the light is emitted from the emitting end surface 220a of the light-emitting element 220 and is incident on the incident lateral surface 243i of the wavelength conversion member 243. In the exemplified example, no other member is interposed between the light-emitting element 220 and the wavelength conversion member 243. This allows downsizing of the light-emitting device 200 in the optical axis OA direction. Another member, such as a collimating lens, may be disposed between the light-emitting element 220 and the wavelength conversion member 243.

As illustrated in FIGS. 4 and 5, in the optical axis OA direction, a width W1 from an inner lateral surface to an outer lateral surface of the lateral portion 241 located on the side of the wavelength conversion member 243 is greater than a width W2 from an inner lateral surface to an outer lateral surface of the lateral portion 241 located on a side opposite to the wavelength conversion member 243. The width W1 is, for example, in a range of 2 times to 10 times of the width W2. The width W2 is, for example, in a range of 100 μm to 500 μm. The width W1 is, for example, is in a range of 300 μm to 1000 μm.

FIG. 14 is an enlarged cross-sectional view of the light-emitting device illustrated in FIG. 4 in which the light-emitting element, the wavelength conversion member, and the vicinity thereof are illustrated in an enlarged manner. As illustrated in FIG. 14, the wavelength conversion member 243 has a shape inwardly recessed at the incident lateral surface 243i. That is, in a top view, a point closest to the emitting end surface 220a of the light-emitting element 220 on the upper surface 243a is located closer to the emitting end surface 220a in the optical axis OA direction than a point closest to the emitting end surface 220a on the lower surface 243b. Furthermore, in the illustrated example, in the optical axis OA direction, a distance L1 from the incident lateral surface 243i of the wavelength conversion member 243 to the emitting end surface 220a of the light-emitting element 220 is longer than a distance L2 from a point, on the upper surface 243a, located furthest in the negative direction (negative direction of the first direction X) of the optical axis OA direction to the emitting end surface 220a.

The distance L1 is, for example, in a range of 50 μm to 300 μm. The distance L2 is, for example, within ±200 μm. The difference between the distance L1 and the distance L2 is, for example, in a range of 50 μm to 500 μm. Thus, regarding the wavelength conversion member 243, the size of the wavelength conversion member 243 in the optical axis OA direction can be increased on the side of the upper surface 243a, which is the emission surface. In addition, the size of the wavelength conversion member 243 in the optical axis OA direction can be reduced on the side of the incident lateral surface 243i, which is a space in which the light-emitting element 220 is disposed.

The case in which the distance L2 has a negative value is a case in which a point located furthest in the negative direction of the optical axis OA direction on the upper surface 243a is located further in the negative direction relative to the emitting end surface 220a. In this case, the upper surface 243a and the emitting end surface of the light-emitting element 220 overlap with each other in a top view. Accordingly, the incident lateral surface 243i is not provided over the entire length of the wavelength conversion member 243 in the third direction Z. Thus, an area of the incident lateral surface 243i can be reduced. For example, it is possible to reduce the light that is incident on the incident lateral surface 243i, is wavelength-converted, and exits again from the incident lateral surface 243i. In addition, at least a part of the upper surface 243a is located further in the negative direction of the optical axis OA direction relative to the incident lateral surface 243i, so that an area of the upper surface 243a can be increased. This contributes to an increase in an area of the exiting surface of the cover 240.

In the direction perpendicular to the upper surface 211a of the base member 211 (that is, the third direction Z), a height H1 of the wavelength conversion member 243 is, for example, the same as a height of the cover 240. In a direction perpendicular to the upper surface 211a of the base member 211, the height H1 of the wavelength conversion member 243 is preferably higher than a height H2 of the closed space formed by the base member 211 and the cover 240. In the cover 240, the height H1 can be in a range of 1.1 times to 2 times of the height H2. The height H1 is, for example, in a range of 300 μm to 700 μm. The height H2 is, for example, in a range of 200 μm to 500 μm. That is, the wavelength conversion member 243 is at least a part of the configuration forming the closed space of the cover 240. Accordingly, it is not necessary to form a closed space by additionally disposing a transparent plate member or the like above the wavelength conversion member 243. This contributes to downsizing of the light-emitting device 200 in the third direction Z.

As described above, in the light-emitting device 200, the light-emitting element 220 is disposed on the upper metal member 231 provided on the upper surface 211a of the base member 211, and the light-emitting element 220 is covered by the cover 240 having a recessed shape. The wavelength conversion member 243, configured to wavelength-convert the light from the light-emitting element 220 and to emit the light to the outside, constitutes a part of the cover 240. With such a configuration, it is not necessary to additionally provide a frame-shaped member that surrounds the periphery of the light-emitting element 220 on the outer peripheral side of the wavelength conversion member 243, so that it is possible to downsize the light-emitting device 200 in the optical axis OA direction. In addition, it is not necessary to additionally provide a member that covers the light-emitting element 220 above the wavelength conversion member 243, the light-emitting device 200 can be downsized in the third direction Z.

A length of the light-emitting device 200 in the first direction X is, for example, in a range of 2500 μm to 4000 μm. A length in the second direction Y is, for example, in a range of 1800 μm to 2500 μm. A length in the third direction Z is, for example, in a range of 500 μm to 1500 μm. Thus, the light-emitting device 200 disclosed in the present description is a light-emitting device suitable for downsizing.

Accordingly, the light-emitting device 200 hindered from increasing in size in the optical axis OA direction can be obtained. In addition, since the closed space in which the light-emitting element 220 is disposed is formed by the cover 240 including the light-shielding member 244 and the wavelength conversion member 243, it is not necessary to additionally form a fitting portion into which the wavelength conversion member is to be fitted.

The light-emitting device 200 can be used, for example, for an on-vehicle headlight. The light-emitting device 200 is not limited to the above and can be used for illumination, a projector, a head-mounted display, and a light source such as a backlight of other displays.

Although the preferred embodiments and the like have been described in detail above, the disclosure is not limited to the above-described embodiments and the like, various modifications and substitutions can be made to the above-described embodiments and the like without departing from the scope described in the claims.

What is claimed is:

1. A light-emitting device comprising:
a base member;
a light-emitting element disposed on an upper surface of the base member and configured to emit light in a lateral direction; and
a cover bonded to the base member and having a lateral portion surrounding a periphery of the light-emitting element and an upper portion arranged above the light-emitting element, the cover including
a wavelength conversion member having an incident surface where the light emitted from the light-emitting element in the lateral direction is incident, at least a part of the wavelength conversion member constituting at least a part of the upper portion of the cover, and
a light-shielding member configured to shield light having a wavelength range identical to a wavelength range of the light emitted from the light-emitting element in the lateral direction, wherein
a straight line, which passes through a light-emitting point of the light-emitting element and is parallel to an optical axis direction, passes through a part of the light-shielding member, the optical axis direction being a direction in which the light emitted from the light-emitting element and passing along an optical axis travels, and
at least the part of the light-shielding member is located, relative to the wavelength conversion member, on a side opposite from the light-emitting element in the optical axis direction.

2. The light-emitting device according to claim 1, wherein
the wavelength conversion member has
a lateral surface including an incident lateral surface constituting the incident surface, and
an upper surface where light obtained by converting a wavelength of the light incident on the incident lateral surface exits upwardly.

3. The light-emitting device according to claim 2, wherein
an upper surface of the wavelength conversion member constitutes at least a part of an upper surface of the cover, and
the incident lateral surface of the wavelength conversion member constitutes at least a part of an inner lateral surface of the cover.

4. The light-emitting device according to claim 1, wherein
an outer lateral surface of the light-shielding member constitutes an entirety of an outer lateral surface of the cover.

5. The light-emitting device according to claim 2, wherein
in the optical axis direction, a distance from an emitting end surface of the light-emitting element to the incident lateral surface of the wavelength conversion member is longer than a distance from the emitting end surface of the light-emitting element to a point of the upper surface of the wavelength conversion member closest to the emitting end surface.

6. The light-emitting device according to claim 1, wherein
in a direction perpendicular to an upper surface of the base member, a height of the wavelength conversion member is greater than a height of a closed space defined by the base member and the cover.

7. The light-emitting device according to claim 1, wherein
in the optical axis direction, a width from an inner lateral surface to an outer lateral surface of a part of the lateral portion of the cover including the wavelength conversion member is greater than a width from an inner lateral surface to an outer lateral surface of a part of the lateral portion located opposite to the wavelength conversion member.

8. The light-emitting device according to claim 2, wherein
a lower surface of the wavelength conversion member constitutes at least a part of a lower surface of the cover, and
in a top plan view, a shape of the lower surface of the wavelength conversion member and a shape of the upper surface of the wavelength conversion member are different.

9. The light-emitting device according to claim 1, wherein
in a top plan view, the light-shielding member covers 80% or more of an upper surface of the light-emitting element.

10. The light-emitting device according to claim 2, wherein
the wavelength conversion member has a first lateral surface and a second lateral surface, the first lateral surface and the second lateral surface being connected with each other on an upper side of the wavelength conversion member and being each connected with the incident lateral surface on a lower side of the wavelength conversion member, and
in the wavelength conversion member, the first lateral surface and the second lateral surface are covered by the light-shielding member and are not exposed, and the incident lateral surface is not covered by the light-shielding member and is exposed.

11. The light-emitting device according to claim 1, wherein
a lateral surface of the light-emitting element located on an opposite side from an emitting end surface of the light-emitting element faces the light-shielding member.

12. The light-emitting device according to claim 1, wherein
each of the wavelength conversion member and the light-shielding member is made of a ceramic as a main material.

13. A method of manufacturing a cover, comprising:
providing a wafer including a plurality of wavelength conversion members disposed two-dimensionally at a predetermined interval and one light-shielding member surrounding a lateral surface of each of the wavelength conversion members in a top view;
forming a plurality of recesses opening on a lower surface of the wafer by removing a part of each of the wavelength conversion members and a part of the light-shielding member without penetrating through the wafer; and
singulating the wafer into a plurality of pieces each constituting the cover by cutting the light-shielding member such that each of the pieces includes a corresponding one of the wavelength conversion members and a corresponding one of the recesses.
